(19) United States
(12) Patent Application Publication
(10) Pub. No.: US 2025/0158354 A1
(43) Pub. Date: May 15, 2025

(54) LASER PACKAGE AND METHOD FOR MANUFACTURING A LASER PACKAGE

(71) Applicant: ams-OSRAM International GmbH, Regensburg (DE)

(72) Inventors: Elmar BAUR, Regensburg (DE); Thomas KIPPES, Neumarkt (DE); Jan MARFELD, Regensburg (DE); Joerg Erich SORG, Regensburg (DE)

(73) Assignee: ams-OSRAM International GmbH, Regensburg (DE)

(21) Appl. No.: 18/833,053

(22) PCT Filed: Jan. 27, 2023
(86) PCT No.: PCT/EP2023/052079

§ 371 Date: Jul. 25, 2024

(30) Foreign Application Priority Data
Jan. 28, 2022 (DE) 10 2022 102 089.4

(51) Int. Cl. H01S 5/024; H01S 5/02315; H01S 5/042

(52) U.S. Cl. CPC H01S 5/02469; H01S 5/02315; H01S 5/0421

(57) ABSTRACT

The invention relates to a laser package comprising a laser device configured to emit laser radiation through at least one laser facet on a front side surface of the laser device; an electrically conductive heat sink; and a contact layer between the laser device and the electrically conductive heat sink comprising a nanowire structure formed of an electrically conductive material. The contact layer comprises at least one first region and at least one second region, and the at least one first region has a higher material density of the electrically conductive material than the at least one second region. In addition, the at least one first region is arranged adjacent to the at least one laser facet.

### CROSS-REFERENCE TO RELATED APPLICATIONS

The present application is a national stage entry from International Application No. PCT/EP2023/052079, filed on Jan. 27, 2023, published as International Publication No. WO 2023/144344 A1 on Aug. 3, 2023, and claims the priority of German patent application No. 10 2022 102 089.4 dated Jan. 28, 2022, the disclosures of which are hereby incorporated by reference into the present application.

### FIELD

The present invention relates to a laser package and a method for manufacturing a laser package.

### BACKGROUND

In the manufacture of laser packages, a semiconductor laser is currently usually mounted on a copper heat sink in order to dissipate the energy generated in the semiconductor laser during its intended use. At the same time, however, it must be ensured that the semiconductor laser does not detach from the copper heat sink due to thermomechanical stresses within the laser package as a result of the energy generated and the associated heating of the laser, or that the electro-optical properties of the laser deteriorate due to thermomechanical stresses. Since the thermal expansion coefficients between copper and the laser substrate materials used for the semiconductor laser, such as GaAs or GaN, are very different (17 ppm/K for Cu vs. 6 ppm/K for GaAs or 3-6 ppm/K for GaN), and if the semiconductor laser and the heat sink are heated there is therefore a risk that thermomechanical stresses may occur between them, the semiconductor laser is currently not mounted directly on the copper heat sink in most cases, but on a so-called submount. The submount can consist of a ceramic carrier with a copper coating (“Cosa”=chip on submount assembly), onto which the semiconductor laser is soldered, for example by means of a solder layer. The thermal expansion coefficient of the submount can be adjusted to a certain extent by the ratio of copper to ceramic thicknesses and can therefore be closer to that of the semiconductor laser than to that of the copper heat sink. The use of a submount therefore represents an improvement in the laser package in terms of the thermal expansion coefficients and the risk of thermomechanical stresses.

Despite the use of a submount, the different thermal expansion coefficients of the materials involved can cause certain thermomechanical stresses on the semiconductor laser, which may not cause the semiconductor laser to detach, but can cause a deterioration in the electro-optical properties of the laser. For example, a shear stress on the semiconductor laser causes a reduction in the polarization purity of the laser (PER=Polarization Extinction Ratio). This can be demonstrated by simulating the shear stress of a typical laser package with submount and copper heat sink. The shear voltage on the semiconductor laser should therefore be kept as low as possible.

One way to further reduce the thermomechanical stresses compared to the use of a submount is to use a contact structure comprising so-called “nanowires” instead of a solder layer to attach the semiconductor laser to the submount or directly to the heat sink. A contact structure with nanowires comprises thin, spaced-apart metal threads (diameter in the range of μm and length−2-pprox. 10 μm to 20 μm), for example made of copper or other metals, which are more flexible than solder layers and can therefore better compensate for thermomechanical stresses. However, the fill factor of the contact structure with nanowires (volume proportion of metal in relation to the total volume of the contact structure) must be sufficiently small to ensure that the contact structure or the nanowires can sufficiently compensate for the thermomechanical stresses. However, a low fill factor of the contact structure with nanowires in turn leads to a lower heat dissipation of the energy generated in the semiconductor laser. When using a contact structure with nanowires, it is therefore also necessary to resolve the conflict of objectives that a high fill factor is required for a good thermal connection, while at the same time a low fill factor is necessary for high flexibility to buffer thermomechanical stresses.

There is therefore a need to specify a laser package and a method for manufacturing a laser package which counteracts at least one of the aforementioned problems.

### SUMMARY OF THE INVENTION

This need is met by a laser package mentioned in claim 1 and by the method for manufacturing a laser package mentioned in claim 15. Further embodiments are the subject of the subclaims.

The core of the invention is to use a contact structure comprising nanowires for electrical and thermal coupling between a semiconductor laser or a laser device and a heat sink or a submount, wherein the contact structure has areas with different fill factors. In particular, the contact structure in sensitive areas of the laser device, for example directly below a laser facet of the laser device, has a higher fill factor for better heat dissipation, whereas the contact structure in less sensitive areas of the laser device has a lower fill factor for better buffering of thermomechanical stresses. This allows the possible advantages of a nanowire structure, namely high flexibility with a low fill factor and high thermal conductivity with a high fill factor, to be combined.

Usually, a contact structure (nanowireing) comprising nanowires is produced with a uniform structure (density of the nanowires). This can result in either insufficient flexibility for buffering thermomechanical stresses or insufficient thermal conductivity. In contrast, the invention proposes structured nanowireing (i.e. a spatially or area-wise changing fill factor of the contact structure), so that possible advantages of nanowireing, namely high flexibility and high thermal conductivity, can be combined.

With a sufficiently high fill factor, a contact structure comprising nanowires can have a high thermal conductivity. For example, for a contact structure made of copper (Cu), for example, with a sufficiently high fill factor compared to solder materials such as a gold-tin alloy (AuSn) (λ_{Cu}=380 W/mK compared to approx. λ_{Ausn}=50 W/mK), there can be no disadvantage in terms of heat dissipation for the contact structure despite a higher layer thickness of the solder material. However, if a high degree of flexibility is required, the density of the nanowires must be low in order to ensure a high degree of freedom of movement. However, this reduces the fill factor and in turn the thermal conductivity. Assuming, for example, a nanowire contact structure with a standard thickness of d=15 μm, i.e. d=15 μm long copper nanowires with a fill factor of 50%, the thermal resistance Rₜₕ of the layer in relation to the unit area A=1 mm² is: Rₜₕ=d/(50%*A*λ_{Cu})=15 μm/(0.5*1 mm²*380 W/mK)=0.079 K/W*m². In contrast, an AuSn solder layer with a standard thickness of d=4 μm and again based on the unit area A=1 mm² has the thermal resistance Rₜₕ=4 μm/(1*1 mm²*50 W/mK)=0.08 K/Wm², i.e. an essentially identical or comparable thermal resistance. In relation to the calculation of the thermal resistance of the contact structure, this can be reduced accordingly for a given thickness of the contact structure or length of the nanowires by increasing the fill factor. A high fill factor is therefore necessary for a good thermal connection. However, a low fill factor is required for high flexibility to buffer thermomechanical stresses. The invention therefore proposes a structured nanowiring of the contact structure. In the areas that are particularly thermally sensitive, namely in the facet area of the laser device, the invention proposes nanowireing with a high fill factor and in other areas nanowireing with a low fill factor.

According to at least one embodiment, a laser package comprises a laser device configured to emit laser radiation through at least one laser facet on a front side surface of the laser device, an electrically conductive heat sink, and a contact layer between the laser device and the electrically conductive heat sink comprising a nanowire structure formed of an electrically conductive material. The contact layer has at least one first region, in particular a volume region, and at least one second region, in particular a volume region, wherein the at least one first region has a higher material density of the electrically conductive material than the at least one second region, and wherein the at least one first region is arranged adjacent to the at least one laser facet.

The term “higher material density” means that the at least one first area has more electrically conductive material in relation to its volume than the at least one second area in relation to its volume.

According to at least one embodiment, the at least one first region has a higher density of nanowires than the at least one second region. In particular, the first region has more nanowires relative to its volume than the at least one second region in turn relative to the volume of the same. The higher material density of the electrically conductive material of the at least one first region can result accordingly from a higher density of nanowires. A higher density of nanowires can result, on the one hand, from the fact that the at least one first region has nanowires that are already arranged closer together than in the at least one second region at the time the nanowires are produced. However, it is also possible that the at least one first region and the at least one second region, at the time of generation of the nanowires, have nanowires which are essentially equidistant from one another, i.e. the density of nanowires in the first and second regions is essentially the same, and the nanowires in the first region are compacted, in particular compressed, only when the electrically conductive contact layer is arranged between the laser device and the electrically conductive heat sink. Such a locally higher density of the nanowires due to a compression of the nanowires can result, for example, due to a step or local increase of an electrically conductive material in the area of the first region on a bottom side of the laser device, or due to a step or local increase of an electrically conductive material in the area of the first region on a top side of the electrically conductive heat sink or on a top side of a submount arranged between the contact layer and the electrically conductive heat sink. In addition, nanowires arranged on the step or in the first region can also be arranged closer to one another than, for example, nanowires of the at least one second region at the time of generation of the nanowires.

According to at least one embodiment, the at least one first region is at least partially formed by a substantially continuous solid material layer of the electrically conductive material. The higher material density of the electrically conductive material of the at least one first region may accordingly result from the substantially continuous solid material layer, which at least partially forms the at least one first region. For example, the entire at least one first region may be formed by the substantially continuous solid material layer, or the at least one first region may comprise a substantially continuous solid material layer and nanowires disposed thereon. In addition, the nanowires arranged on the substantially continuous solid material layer may in turn be arranged closer to each other than, for example, nanowires of the at least one second region.

According to at least one embodiment, the at least one first region extends along or below the entire front side surface of the laser device.

According to at least one embodiment, the at least one first region is arranged directly below the at least one laser facet, as viewed in the direction of the at least one front side surface, and in particular is arranged between two second regions. Accordingly, the at least one first region can be located directly below the at least one laser facet, but not below the lateral regions next to the at least one laser facet.

According to at least one embodiment, the at least one first region extends from the front side surface of the laser device to a rear side surface of the laser device opposite the front side surface. For example, the laser device may be formed by a laser diode and have at least one resonator, and the at least one first region extends over the entire resonator length below the resonator.

According to at least one embodiment, the at least one first region extends from the front side surface of the laser device in the direction of a rear side surface of the laser device opposite the front side surface, but not as far as the rear side surface of the laser device. In particular, the at least one second region can adjoin the at least one first region in the direction from the front side surface to the rear side surface of the laser device.

According to at least one embodiment, the at least one first region is small, in particular 2-fold, 5-fold or 10-fold smaller than the at least one second region. This is because the degree of polarization of the laser device varies due to shear stresses over the entire contact area between the laser device and the contact layer, and in particular over the entire area from the front side surface of the laser device to a rear side surface of the laser device opposite the front side surface. The area with a lower fill factor or a lower material density of the electrically conductive material, i.e. the at least one second area, should therefore be selected to be significantly larger than the area with a higher fill factor or a higher material density of the electrically conductive material, i.e. the at least one first area.

According to at least one embodiment, the laser device is formed by a multi-ridge laser diode, in particular an edge-emitting multi-ridge laser diode, with at least one laser channel. However, the multi-ridge laser diode can also have several closely adjacent separate laser channels, each of which emits light of at least a slightly different wavelength. However, it is also conceivable that the laser channels emit light of essentially the same wavelength.

According to at least one embodiment, the laser device has a second laser facet, adjacent to the at least one first laser facet, on the front side surface of the laser device. The laser device may, for example, be a multi-ridge laser diode, in particular an edge-emitting multi-ridge laser diode, with at least two laser channels. Each of the at least two laser channels opens into a laser facet through which the laser device emits laser light during intended use of the laser device.

According to at least one embodiment, the contact layer has a further first region which is arranged adjacent to the second laser facet. In particular, a first region of the contact layer can be arranged directly below the first laser facet, and a further first region of the contact layer can be arranged directly below the second laser facet.

According to at least one embodiment, a second area of the contact layer is arranged between the two first areas of the contact layer. In addition, a second area can also be arranged to the side of each of the two first areas of the contact layer. The areas of the contact layer with a higher fill factor or a higher material density of the electrically conductive material can accordingly only be limited to areas directly below a laser facet.

According to at least one embodiment, the laser device is formed by a laser diode, in particular by an edge-emitting laser diode. The laser diode can, for example, be operated in pulsed mode during its intended use. In some embodiments, however, it may also be desirable for it to be operated continuously.

According to at least one embodiment, the laser device is configured to emit blue laser light or laser light with a wavelength in a wavelength range from approximately 400 nm to approximately 500 nm. However, this should not be understood as limiting, as the laser device can also be configured to emit laser light of any other color, such as red, green, infrared or ultraviolet. In particular, the laser device can be configured to emit laser light with a high power density in the area of the laser facet, regardless of the size of the laser device. For example, the laser device can be a high-power laser diode.

According to at least one embodiment, the laser package also comprises a submount, which is arranged between the heat sink and the contact layer. The submount comprises, for example, a ceramic base carrier with an electrically conductive coating on the top and bottom. For example, the base carrier can be made of a ceramic material such as aluminum nitride (AlN) and the electrically conductive coating can be formed by a metal such as copper (Cu).

According to at least one embodiment, the submount is attached to the heat sink by means of a solder layer. However, the submount can also be attached to the heat sink by means of a differently formed contact layer. For example, the submount can be arranged on the heat sink by means of a nanowire structure.

According to at least one embodiment, the laser package further comprises a carrier substrate having at least one electrical contact surface on a top surface of the carrier substrate, wherein the heat sink is arranged on the at least one electrical contact surface.

According to at least one embodiment, the laser package further comprises a housing cover which is arranged on the top surface of the carrier substrate and forms a cavity together with the carrier substrate such that the electrically conductive heat sink and the laser device are arranged in the cavity.

According to at least one embodiment, the housing cover is attached to the carrier substrate by means of an adhesive layer. The adhesive layer can be formed from an inorganic material, for example, and the laser package can be hermetically encapsulated by means of the inorganic adhesive layer, the carrier substrate and the housing cover. This can increase the service life of the laser package.

According to at least one embodiment, the laser package further comprises a getter material, in particular comprising oxygen, which is arranged in the contact layer. For example, the getter material can be arranged in gaps or on the surface of the nanowires. The getter material can be used in particular to render any organic molecules in the cavity harmless due to the manufacturing process of the laser package or due to the intended use of the laser package, so that they cannot cause degradation of the laser facet. If a getter material is used, the adhesive layer can also comprise an organic material so that the laser package is not hermetically encapsulated, but organic molecules can outgas from the adhesive layer into the cavity of the laser package or diffuse into it. With the aid of the getter material, however, these organic molecules can be rendered harmless so that they do not lead to degradation of the at least one laser facet.

A method of manufacturing a laser package is further proposed, comprising the steps of:
Providing a laser device configured to emit laser radiation through at least one laser facet on a front side surface of the laser device;
Providing an electrically conductive heat sink; and
Providing a contact layer between the laser device and the electrically conductive heat sink;
wherein the contact layer comprises a nanowire structure formed from an electrically conductive material;
wherein the contact layer has at least one first region and at least one second region and the at least one first region has a higher material density of the electrically conductive material than the at least one second region, and
wherein the at least one first region is arranged adjacent to the at least one laser facet.

According to at least one embodiment, the step of providing the contact layer comprises providing a filter foil or mask for creating the nanowire structure. For example, an ion track-etched filter foil can be used to form the nanowire structure. Ion track-etched filter foils, for example made of polycarbonate (PC), polyimide (PI) or polyethylene terephthalate (PET), can serve as a mask for the galvanic deposition of “metal straws” or nanowires, as these have cavities or through-holes due to the ion track etching, which can then be filled again. By re-moving the filter foil after the cavities or through-holes have been filled with a desired material, this remains in the form of periodically or randomly arranged “metal straws” or nanowires. Such filter foils can have a thickness of up to 25 μm with cavities or through-holes with a diameter of 15 nm and larger. For the present invention, a PC filter film with a pore or cavity diameter of 100 nm can be used in a preferred manner, for example, so that nanowires with a diameter of 100 nm and a length of approx. 2 μm can be produced.

According to at least one embodiment, the filter foil or mask has at least one first region and at least one second region, wherein the at least one first region has a higher density of cavities and/or through-holes than the at least one second region. After the cavities or through-holes have been filled with a desired material and the filter foil has subsequently been removed, areas with different densities of nanowires can thus be produced.

According to at least one embodiment, the step of providing the contact layer comprises forming a substantially continuous solid material layer of the electrically conductive material in the at least one first region. For example, the step of providing the contact layer may comprise growing a substantially continuous solid material layer of the electrically conductive material in the at least one first region, on which a nanowire structure is subsequently formed.

According to at least one embodiment, the step of providing the contact layer comprises at least partially filling gaps between nanowires of the nanowire structure in the at least one first region. As a result, a substantially continuous solid material layer can be at least partially produced in the first region, which at least partially embeds and connects the nanowires in the at least one first region.

According to at least one embodiment, the method also comprises providing a submount between the heat sink and the contact layer, wherein the submount comprises a ceramic base support, on the top and bottom sides of which an electrically conductive coating is formed.

According to at least one embodiment, the method further comprises providing a carrier substrate having at least one electrical contact surface on a top surface of the carrier substrate, wherein the heat sink is subsequently arranged on the at least one electrical contact surface.

According to at least one embodiment, the method further comprises providing a housing cover on the top surface of the carrier substrate, which together with the carrier substrate forms a cavity such that the electrically conductive heat sink and the laser device are arranged in the cavity.

According to at least one embodiment, the step of arranging the housing cover on the top surface of the carrier substrate comprises adhering the housing cover to the top surface of the carrier substrate by means of an adhesive layer. In particular, the adhesive layer can be a layer made of an inorganic material in order to hermetically encapsulate the laser package. However, the adhesive layer can also comprise an organic material by means of which the laser package is encapsulated, in particular not hermetically encapsulated.

### BRIEF DESCRIPTION OF THE DRAWINGS

In the following, embodiments of the invention are explained in more detail with reference to the accompanying drawings. They show, in each case schematically,

FIG. 1 a laser package comprising a laser device on a submount; and

FIGS. 2 to 11 embodiments of a laser package according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in prac-tice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

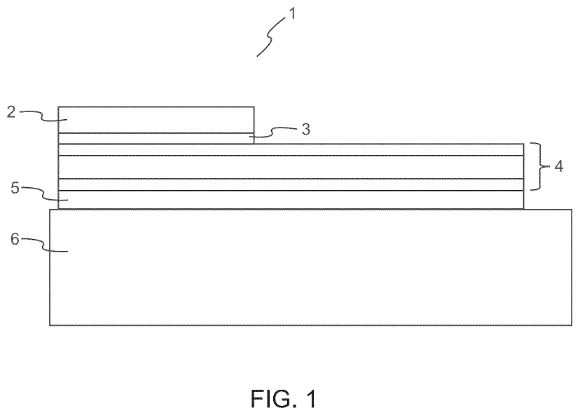

FIG. 1 shows a schematic sketch of a typical laser package 1 with a laser diode or a laser chip 2, which is soldered to a submount 4 by means of a first solder layer 3, and this submount 4 is applied to a heat sink 6, in particular a copper heat sink, by means of a second solder layer 5. The submount 4 consists of a ceramic carrier with a copper coating, onto which the laser chip 2 is soldered by means of the first solder layer. Specif-ically, the submount 4 can, for example, comprise an AlN core with a thickness of approx. 350 μm and a copper coating on both sides, each with a thickness of approx. 60 μm. The solder used for the first solder layer 3 is usually AuSn, whereas the cosa, i.e. the submount 4 with the laser chip 2 arranged on it, is soldered onto the copper heat sink 6 using a SnAgCu or SnInAg solder layer as the second solder layer 5.

The thermal expansion coefficient of the submount 4 can be adjusted by the ratio of copper to ceramic thickness and can therefore be closer to that of the laser chip 2 than to that of the copper heat sink 6, so that lower thermomechanical stresses already occur in the laser package 1 during operation compared to direct application of the laser chip 2 to the heat sink 6. However, the different thermal expansion coefficients of the materials involved can cause undesirable thermomechanical stresses on the laser chip 2. Although these thermomechanical stresses do not necessarily lead to the laser chip 2 becoming detached, they can cause a deterioration in the electro-optical properties of the laser.

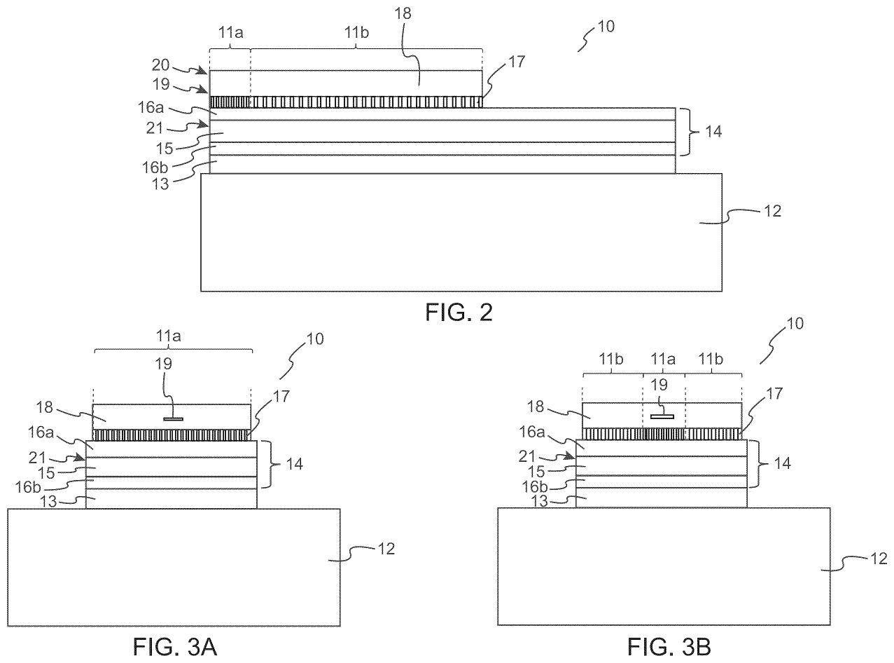

An improved laser package is therefore proposed, which has both good heat dissipation and good buffering of thermomechanical stresses. Such a laser package or possible embodiments thereof according to some aspects of the proposed principle are shown in FIGS. 2 to 9.

FIG. 2 shows a side view of a laser package 10 comprising an electrically conductive heat sink 12, to which a submount 14 is attached by means of a solder layer 13. The submount 14 comprises a base carrier 15, on the top and bottom sides of which an electrically conductive coating 16a, 16b is formed. The solder layer 14 is adjacent to the electrically conductive coating 16b on the underside of the submount 14.

An electrically conductive contact layer 17 is arranged on the submount 14 or above the heat sink 12, which electrically couples the submount 14 and a laser device 18, which is arranged on the electrically conductive contact layer 17, to one another. The laser device 18 is configured to emit laser radiation through a laser facet 19 on a front side surface 20 of the laser device 18. In particular, the laser device 18 is arranged on the submount 14 in such a way that the laser facet 19 lies essentially in the same plane as an underlying side surface 21 of the submount 14 or projects beyond it. This prevents so-called beam clipping of the laser radiation emitted by the laser device 18 through the submount 14 or through the underlying heat sink 12.

The contact layer 17 comprises a nanowire structure made of an electrically conductive material and has a first volume area 11a and a second volume area 11b. The first region 11a has a higher material density of the electrically conductive material or higher nanowire density than the second region 11b, and the first region 11a is arranged adjacent to the laser facet 19. Due to the high flexibility of the nanowires of such a nanowire structure, thermomechanical stresses caused by different thermal expansion coefficients of the laser device 18 and the submount 14 can be buffered. In addition, by structuring the contact layer 17 into a first and a second area 11a, 11b with different fill factors of the electrically conductive material, a high thermal conductivity can also be provided, at least in the area with the higher fill factor.

The embodiment shown in FIG. 2 shows a structuring of the contact layer 17 in the form of a spatial change in the nanowire density from the front side surface 20 of the laser device in the direction of a rear side surface of the laser device opposite the front side surface 20. In particular, the contact layer 17 below the laser facet 19 has a decreasing density of nanowires or electrically conductive material from the front side surface 20 of the laser device towards the rear side surface of the laser device. For example, the laser device 18 may be formed by a laser diode and have a resonator, and the contact layer 17 may have a spatial change in nanowire density along the resonator.

FIGS. 3A and 3B show possible front views of the laser package 10 of FIG. 2. As shown in FIG. 3A, the first region 11a may extend along the entire front side surface 20, and thus the contact layer 17 may have a higher density of nanowires along the entire front side surface 20. On the other hand, it is also conceivable that, as shown in FIG. 3B, the nanowire density changes along the front side surface 20, i.e. perpendicular to the resonator direction. In this case, the first area 11a is arranged directly below the laser facet 19 and a second area 11b is arranged adjacent to the first area. In the event that the front view shown in FIG. 3B correlates to the laser package 10 shown in FIG. 2, the first region is essentially located only below the laser facet 19 both along the front side surface 20 and perpendicular to it. However, the embodiment shown in FIG. 3B can also be understood in such a way that the nanowire density varies only along the front side surface 20, but not perpendicular to the front side surface 20, i.e. in the resonator direction. Accordingly, the nanowire density can be higher in the center of the laser device 18 so that the thermal conductivity of the contact layer 17 is increased in the region of the heat-loss generating p-n junction of the laser device 18.

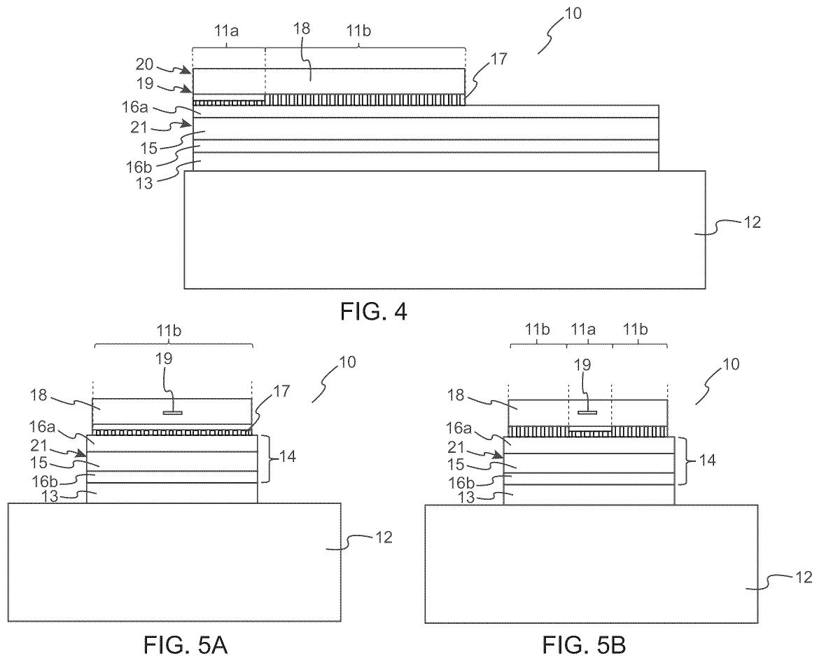

FIG. 4 shows a further embodiment example of the laser package 10, in which the first region 11a of the contact layer 17 is at least partially formed by a substantially continuous solid material layer of the electrically conductive material. A high thermal conductivity of the contact layer 17 is achieved in the facet area, i.e. in the first area, by a “step” in the form of a substantially continuous solid material layer below the laser facet 19. The step or solid material layer can be formed from the same electrically conductive material as the nanowire structure, but can also be formed from another material with a high thermal conductivity, such as gold. Nanowires are also arranged on the step, but are shorter in this area due to the step. Due to the solid material layer and the nanowires arranged on it, the contact layer 17 in the first area 11a has a higher fill factor or a higher material density, so that the thermal conductivity in this area is increased. In the second area 11b without a step, the nanowires are longer and have a correspond-ingly lower fill factor and therefore lower thermal conductivity, but greater flexibility. In the case shown, the nanowires of the contact layer are arranged essentially uniformly relative to each other both in the first area 11a and in the second area 11b, and an increased material density results in the first area due to the step. However, it is also possible that the contact layer 17 in the first region also has an increased density of nanowires compared to the second region, or is formed entirely by a solid material layer.

FIGS. 5A and 5B again show possible front views of the laser package 10 of FIG. 4. As shown in FIG. 5A, the first region 11a can extend along the entire front side surface 20, and thus the contact layer 17 can have a higher material density or a higher fill factor along the entire front side surface 20. On the other hand, it is also conceivable that, as shown in FIG. 5B, the material density or the fill factor changes along the front side surface 20, i.e. perpendicular to the resonator direction. In this case, the first area 11a is arranged directly below the laser facet 19 and a second area 11b is arranged adjacent to the first area. In the event that the front view shown in FIG. 5B correlates to the laser package 10 shown in FIG. 4, the first region is essentially located only below the laser facet 19 both along the front side surface 20 and perpendicular to it. However, the embodiment shown in FIG. 5B can also be understood in such a way that the nanowire density varies only along the front side surface 20, but not perpendicular to the front side surface 20, i.e. in the resonator direction. The material density or the fill factor can accordingly be higher in the center of the laser device 18, so that the thermal conductivity of the contact layer 17 is increased in the region of the heat-loss generating p-n junction of the laser device 18.

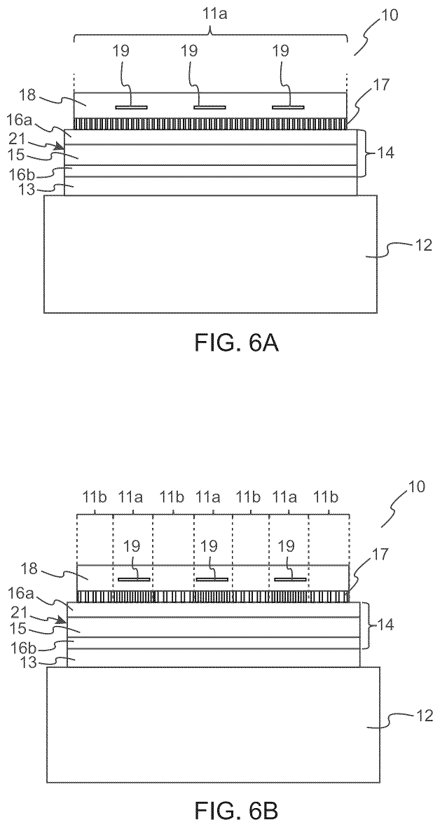

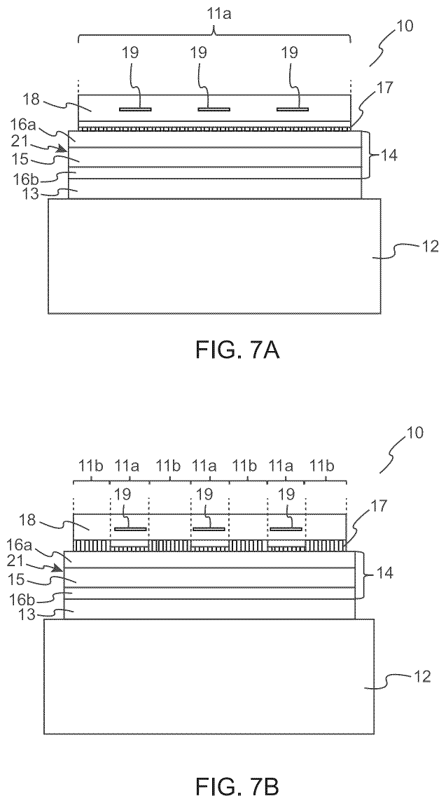

FIGS. 6A to 7B show front views of further possible embodiments of the laser package 10. Contrary to FIGS. 3A and 3B and FIGS. 5A and 5B, the laser device 18 in each case has three laser channels adjacent to one another, i.e. also three laser facets 19 adjacent to one another in each case. Accordingly, the laser device 18 can be a multi-ridge laser diode.

According to FIG. 6A, the first region 11a extends along the entire front side surface 20, and thus the contact layer 17 has a higher density of nanowires along the entire front side surface 20. However, it is also conceivable that, as shown in FIG. 6B, the nanowire density changes along the front side surface 20, i.e. perpendicular to the resonator direction, and in each case a first region 11a is located directly below a laser facet 19, and first regions are separated or framed by second regions 11b.

The same also applies to FIGS. 7A and 7B, according to which the first region 11a, as shown in FIG. 7A, extends along the entire front side surface 20, and thus the contact layer 17 has a higher material density or a higher fill factor along the entire front side surface 20. On the other hand, it is also conceivable that, as shown in FIG. 7B, the material density or the fill factor changes along the front side surface 20, i.e. perpendicular to the resonator direction, and a first region 11a is located directly below a laser facet 19 in each case, and the first regions are separated or framed by second regions 11b.

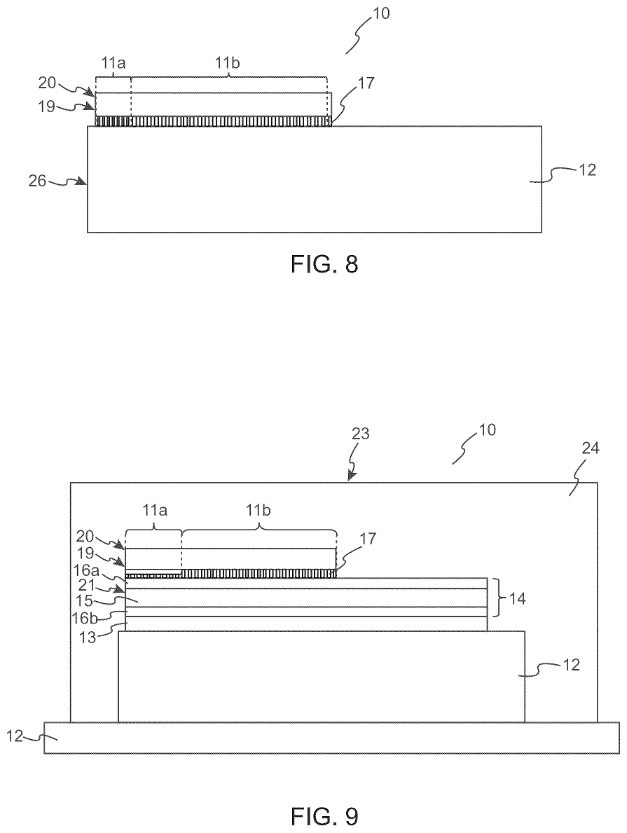

FIG. 8 shows a further embodiment of a laser package according to some aspects of the proposed principle. In contrast to the laser package 10 shown in FIG. 2, the laser device 10 is arranged directly on the heat sink 12, and the submount 14 has been dispensed with. In this case, the laser device 18 is arranged on the heat sink 12 in such a way that the laser facet 19 of the laser device 18 lies essentially in the same plane as an underlying side surface 26 of the heat sink 12 or projects beyond it. This in turn prevents beam clipping of the laser radiation emitted by the laser device 18 by the underlying heat sink 12.

FIG. 9 shows a further laser package 10 comprising a carrier substrate 11 with an electrical contact surface on a top surface of the carrier substrate 11. The electrically conductive heat sink 12, which is electrically coupled to the electrical contact surface or the carrier substrate 11, is arranged on the electrical contact surface or on the carrier substrate 11. The submount 14, comprising a base carrier 15 and the electrically conductive coatings 16a, 16b, is arranged on the heat sink 12 by means of the solder layer 13.

The contact layer 17, comprising the first and second areas 11a, 11b, is arranged on the submount 14 and electrically couples the submount 14 and the laser device 18 to one another. The laser package 10 is encapsulated by means of a housing cover 23, which is arranged on the top surface of the carrier substrate 11. The housing cover 23 forms a cavity 24 with the carrier substrate 11, in which the electrically conductive heat sink 12, the submount 14, the laser device 18 and the contact layer 17 are arranged. The housing cover 23 can, for example, be attached to the carrier substrate 11 with an adhesive layer or a solder layer and hermetically or non-hermetically encapsulate the laser package. In the case of non-hermetic encapsu-lation, a getter material can be formed in the contact layer in order to render harmful molecules, in particular organic molecules, harmless within the cavity 24 during intended use of the laser package 10.

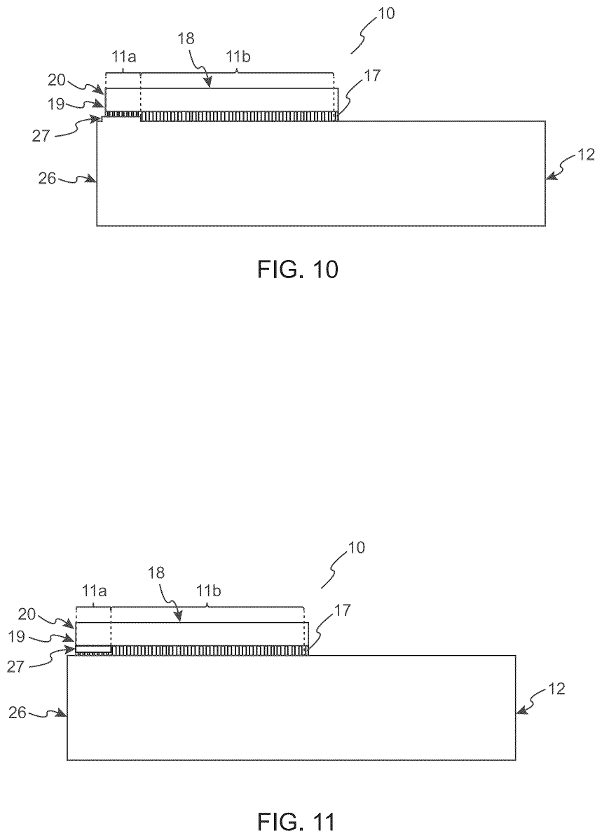

FIGS. 10 and 11 show two possible further embodiments of a laser package 10 according to some aspects of the proposed principle. A higher density in the first region 11a of the contact layer 17 is achieved in FIG. 10 by the heat sink 12 having a step 27 or a local increase in the region of the first region 11a, which causes nanowires of the contact layer 17 to be compressed more in the region of the step 27, in particular to be pressed together, than in the second region 11b without a step. The nanowires can be essentially equidistant from one another at the time of generation of the nanowires, the density of nanowires in the first and second regions can therefore be essentially the same, and only the arrangement of the electrically conductive contact layer 17 between the laser device 18 and the electrically conductive heat sink 12 can lead to a compression of the nanowires in the first region 11a. It is also conceivable that it is not the heat sink 12 but a submount arranged between the contact layer 17 and the electrically conductive heat sink 12 that has the step that leads to a densification of the nanowires.

FIG. 11 shows an embodiment in which the step 27 is present on the underside of the laser device 18. This may be a step 27 created during the generation of metallization layers of the laser device 18, or a step applied at a later time, which is formed in the area of the first region 11a on the underside of the laser device 18. As also described for the above embodiment, the higher density of the contact layer 17 in the first region 11a can result from the fact that, due to the step 27 or local increase in the region of the first region 11a, the nanowires of the contact layer 17 are compacted more, in particular compressed, than in the second region 11b without the step.

1. A laser package comprising:
a laser device configured to emit laser radiation through at least one laser facet on a front side surface of the laser device;
an electrically conductive heat sink; and
a contact layer between the laser device and the electrically conductive heat sink, comprising a nanowire structure formed of an electrically conductive material;
wherein the contact layer comprises at least one first region and at least one second region each comprising the electrically conductive material and the at least one first region has a higher material density of the electrically conductive material than the at least one second region, and
wherein the at least one first region is arranged adjacent to the at least one laser facet.

2. The laser package according to claim 1, wherein the at least one first region has a higher density of nanowires than the at least one second region.

3. The laser package according to claim 1, wherein the at least one first region is at least partially formed by a substantially continuous solid material layer of the electrically conductive material.

4. The laser package according to claim 1, wherein the electrically conductive heat sink or the laser device or a submount arranged between the heat sink and the contact layer comprises a step made of an electrically conductive material in a region opposite the first region.

5. The laser package according to claim 1, wherein the at least one first region extends along the entire front side surface of the laser device.

6. The laser package according to claim 1, wherein the at least one first region is arranged below the at least one laser facet and in particular between two second regions, as seen in the direction of view onto the at least one front side surface.

7. The laser package according to claim 1, wherein the at least one first region extends from the front side surface to a rear side surface of the laser device opposite the front side surface.

8. The laser package according to claim 1, wherein the laser device comprises a second laser facet adjacent to the at least one first laser facet on the front side surface of the laser device.

9. The laser package according to claim 8,
wherein the contact layer comprises a further first region which is arranged adjacent to the second laser facet.

10. The laser package according to claim 1, further comprising a submount which is arranged between the heat sink and the contact layer, the submount comprising a ceramic base support, on the top and bottom sides of which an electrically conductive coating is formed in each case.

11. The laser package according to claim 10,
wherein the submount is attached to the heat sink by means of a solder layer.

12. The laser package according to claim 1, further comprising a carrier substrate having at least one electrical contact surface on a top surface of the carrier substrate, wherein the heat sink is arranged on the at least one electrical contact surface.

13. The laser package according to claim 12,
further comprising a housing cover which is arranged on the top surface of the carrier substrate and together with the carrier substrate forms a cavity such that the electrically conductive heat sink and the laser device are arranged in the cavity.

14. The laser package according to claim 1, further comprising a getter material, in particular comprising oxygen, arranged in the contact layer.

15. A method for manufacturing a laser package comprising:
providing a laser device configured to emit laser radiation through at least one laser facet on a front side surface of the laser device;
providing an electrically conductive heat sink; and
providing a contact layer between the laser device and the electrically conductive heat sink;
wherein the contact layer comprises a nanowire structure formed from an electrically conductive material;
wherein the contact layer comprises at least one first region and at least one second region each comprising the electrically conductive material and the at least one first region has a higher material density of the electrically conductive material than the at least one second region, and
wherein the at least one first region is arranged adjacent to the at least one laser facet.

16. The method according to claim 15, wherein the step of providing the contact layer comprises providing a patterned filter foil for creating the nanowire structure.

17. The method according to claim 16, wherein the structured filter film comprises at least one first region and at least one second region, and the at least one first region has a higher density of voids and/or through-holes than the at least one second region.

18. The method according to claim 15, wherein providing the contact layer comprises forming a substantially continuous solid material layer of the electrically conductive material in the at least one first region.

19. The method according to claim 15, wherein providing the contact layer comprises at least partially filling gaps between nanowires of the nanowire structure in the at least one first region.

20. The method according to claim 15, further comprising providing a submount between the heat sink and the contact layer, wherein the submount comprises a ceramic base support having an electrically conductive coating formed on the top and bottom sides thereof, respectively.

21. The method according to claim 15, further comprising providing a carrier substrate having at least one electrical contact surface on a top surface of the carrier substrate, wherein the heat sink is subsequently arranged on the at least one electrical contact surface.

22. The method according to claim 21, further comprising providing a housing cover on the top surface of the carrier substrate, which together with the carrier substrate forms a cavity such that the electrically conductive heat sink and the laser device are arranged in the cavity.
